(19) United States
(12) Patent Application Publication
(10) Pub. No.: US 2013/0050003 A1
(43) Pub. Date: Feb. 28, 2013

(54) SIGMA-DELTA ANALOG TO DIGITAL CONVERTER

(71) Applicant: JINJU WANG, Santa Clara, CA (US)

(72) Inventor: JINJU WANG, Santa Clara, CA (US)

(73) Assignee: National Semiconductor Corporation, Santa Clara, CA (US)

(21) Appl. No.: 13/217,159

(22) Filed: Aug. 24, 2011

(51) Int. Cl. H03M 3/02; H03M 1/12

(52) U.S. Cl. 341/143; 341/172

(57) ABSTRACT

A ΣΔ analog-to-digital converter is disclosed. In a sampling phase, first and second input signals of an analog differential input signal pair are sampled on respective first and second sampling capacitors and first and second reference signals are sampled on respective third and fourth sampling capacitors. During a subsequent sample/integration phase, the first and second input signals are sampled on the respective second and first sampling capacitors and the first and second reference signals are sampled on the respective fourth and third sampling capacitors. In addition, charges present on the sampling capacitors are transferred to a pair of integrating capacitors that form part of a differential integrator. A quantizer circuit responsive to the integrator output provides the digital output of the converter. Thus, correlated double sampling is carried out, with dynamic element matching of the sampling capacitor being a further option.

### BACKGROUND OF THE INVENTION

1. Field of the Invention

The present invention relates generally to data converters and in particular to delta-sigma analog-to-digital converters with a high common mode rejection ratio.

2. Description of Related Art

There are a wide range of analog-to-digital converter (ADC) types, each having advantages and disadvantages. Sigma-delta analog-to-digital converters (ΣΔADC) are advantageous for high precision applications because they are less sensitive to the non-ideality of analog components as compared to other ADC types. However, traditional ΣΔADCs are in common use in many communication systems where only a high signal to noise ratio is important. As a result, such traditional ΣΔADCs are not believed to be capable of providing good values of CMMR and CMVR which are very important for many high precision applications.

Referring to the drawings, FIG. 1 depicts one prior art solution to this problem. A conventional ΣΔADC 10 is shown which provides modest values of CMRR and CMVR. An analog front end in the form of an instrumentation amplifier 11 is inserted between the analog input Vin+ and Vin− and ΣΔADC 10 to provide improved CMRR and CMVR. The instrumentation amplifier includes a pair of operational amplifiers which provide a high input impedance followed by a differential amplifier stage to provide improved CMRR. However, there are various problems with this approach. First, the CMRR is limited by resistor matching in the instrumentation amplifier 11 to less than 100 dB when the converter is implemented in integrated circuit form. In addition, the instrumentation amplifier consumes excessive power and a large amount of die area.

There is a need for a ΣΔADC which provides the traditional advantages of that converter type along with very good values of CMRR and CMVR and which can also be readily implemented in integrated circuit form. As will become apparent to those skilled in the art upon a reading of the following Detailed Description of the Invention together with the drawings, the present invention addresses these needs.

### BRIEF DESCRIPTION OF THE DRAWINGS

FIG. 1 is a block diagram of a prior art ΣΔ Analog to Digital Converter (ΣΔADC) with an analog front end in the form of an instrumentation amplifier to provide improved CMRR performance.

FIG. 2 is block diagram of a prior art ΣΔADC.

FIG. 3 is a more detailed circuit diagram of a prior art ΣΔADC.

FIGS. 4A to 4C illustrate certain operational features of the FIG. 3 prior art ΣΔADC.

FIGS. 5A to 5C illustrate certain other operational features of the FIG. 3 prior art ΣΔADC.

FIG. 6 is a circuit diagram of one embodiment of the present invention.

FIGS. 7A to 7C illustrate the correlated double sampling operation of the FIG. 6 embodiment.

FIGS. 8A to 8C illustrate the improved common mode rejection ratio (CMRR) aspects of the FIG. 6 embodiment.

FIG. 9 shows the common mode transfer function of the FIG. 6 embodiment.

FIG. 10 shows a further embodiment of the present invention utilizing dynamic element matching for the input sampling capacitors.

FIGS. 11A and 11B are timing diagrams for the clocks used in the FIG. 10 embodiment.

FIG. 12 shows a still further embodiment of the present invention utilizing dynamic element matching for the input sampling capacitors.

FIGS. 13A to 13B are timing diagrams for the clocks used in the FIG. 12 embodiment.

FIG. 14 is a simplified diagram of a clock generator.

### DETAILED DESCRIPTION OF THE INVENTION

Referring to the drawings, FIG. 2 is a simplified diagram showing the basic components of a conventional second order sigma-delta analog-to-digital converter (ΣΔADC). The analog input U to the converter is fed to summing junction 12 where it is combined with an analog feedback signal W. The source of signal W is a digital-to-analog converter which provides a signal plus quantization noise of the analog-to-digital converter (ADC) 16 to the summing junction 12 so that the output of the summing junction represents the difference between the two inputs U and W to the junction. The summing junction output is fed to a first integrator Int1 followed by a second integrator Int2 with the number of integrators determining the order of the converter. The analog output of Int2 is converted to a digital signal by an analog-to-digital converter (ADC) 16, sometimes referred to as a quantizer, which provides a digital signal D that controls DAC 14. Although not depicted, ΣΔADC 10 is followed by a low pass digital filter which removes the out-of-band high frequency quantization noise produced by ADC 16. The negative feedback forces the low frequency portion of signal W to be equal to the input signal U. Note that both DAC 14 and ADC 16 are typically one bit devices although a higher number of bits are sometimes used.

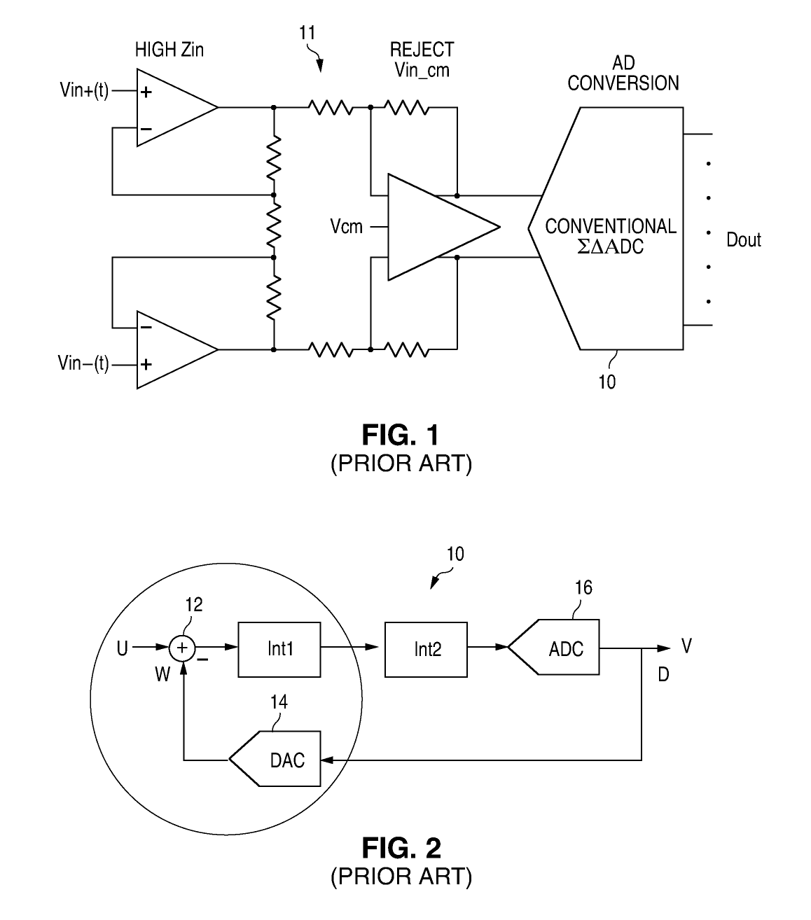

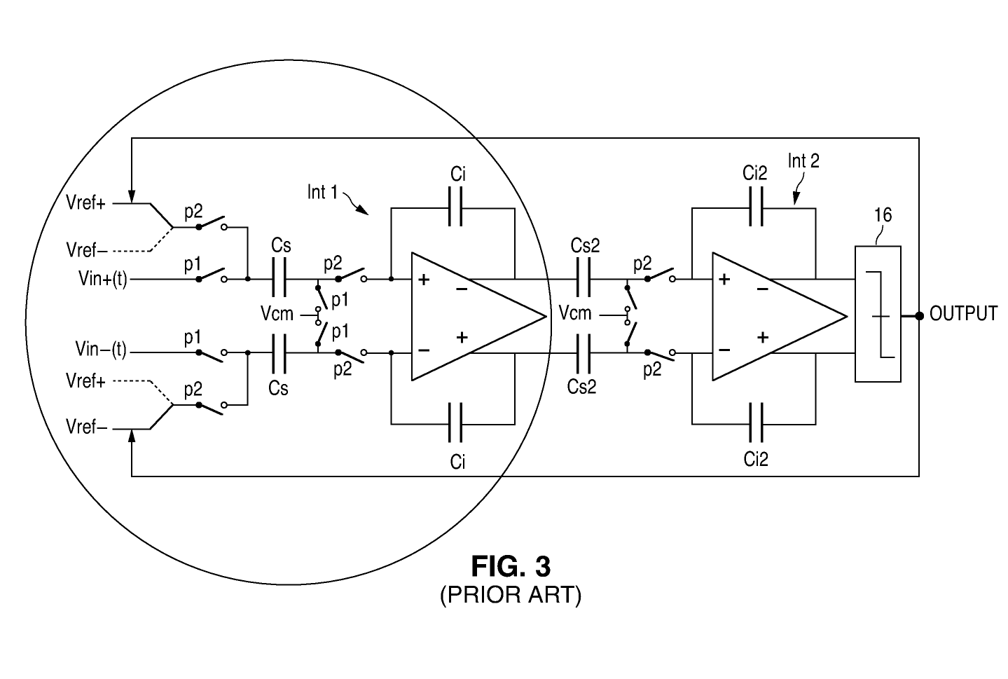

In order to more clearly set forth the various aspects of the present invention, construction and operation will be described along side that of a prior art implementation. FIG. 3 shows the prior art implementation to be used in this comparison. The circled components of FIG. 3 generally correspond to the circled components of FIG. 1. The integrators Int1 and Int2 of FIG. 3 are implemented using switched capacitor circuitry. The various switches depicted in FIG. 3 include two sets of switches controlled by either a clock p1 or a clock p2 so that, generally speaking, when one set of switches is ON, the other set is OFF. The output of Int2 is sent to a quantizer or ADC 16 which converts the analog input to a one bit output. When the output is low, a reference voltage Vref+ is applied to the upper capacitor Cs of FIG. 3 and a reference voltage Vref− is applied to the lower capacitor Cs. When the output is high, voltage Vref− is applied to the upper capacitor Cs and voltage Vref+ is applied to the lower capacitor Cs. Thus, the circuitry for selecting which polarity of Vref will be used together with the switches for selectively applying the reference voltages to the capacitors Cs perform the function of DAC 14 (FIG. 2). An exemplary value of Vref+ is +1 V and −1 V for Vref−. The analog inputs to the converter of FIG. 3 are a differential signal pair including inputs Vin+(t) and Vin−(t).

An analysis of the common mode rejection ratio (CMRR) properties of the FIG. 3 converter demonstrates one its shortcomings. The CMRR of a differential gain stage is a measure of the stage capability to amplifier differential input signals and reject common mode input signals. In other words, the differential gain A_{d} should greatly exceed common mode gain A_{cm}, with CMRR being defined as 20 log [A_{d}/A_{cm}]dB. By way of example, in electrocardiograph (ECG) applications, the differential signals produced by the human body which need to be measured may be on the order of 5 mV so that around a 5 μV measurement accuracy is needed. These ECG signals are in a frequency range of 0.01 to 200 Hz. These small signals are in the presence of much larger common mode signals produced by AC power sources having a frequency of 50/60 Hz. Under these conditions, a CMRR in excess of 100 dB is needed.

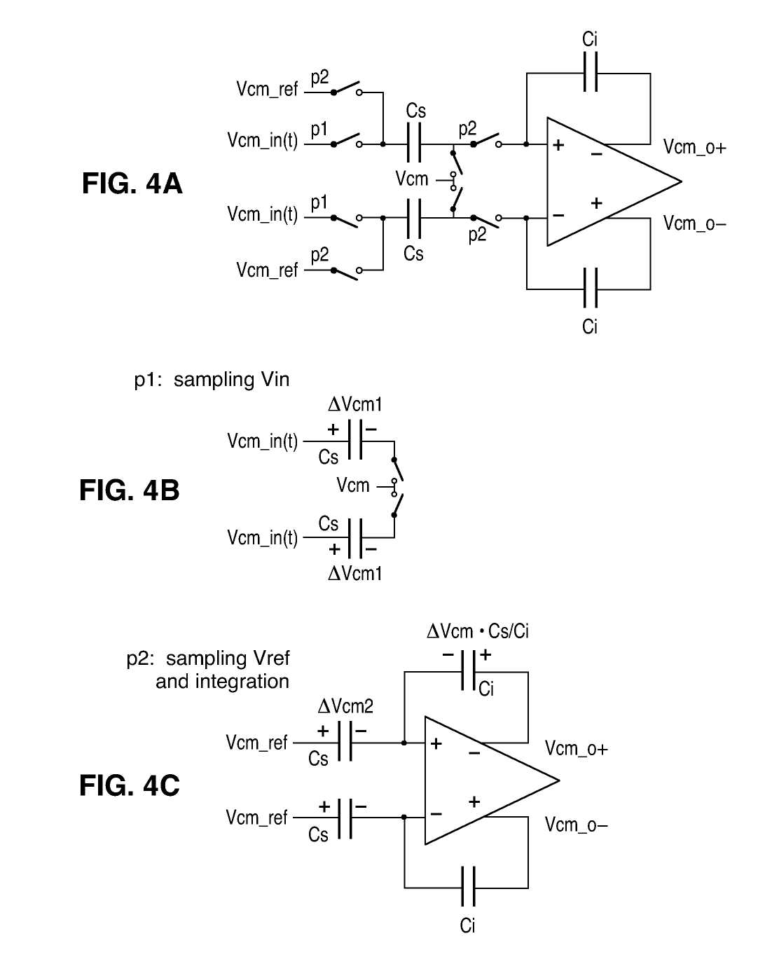

FIGS. 4A-4C illustrate a CMRR analysis of the input section of the prior art ΣΔADC converter of FIG. 3. The inputs to the circuit of FIG. 4A are all common mode inputs including Vcm_ref for the reference voltages Vref+ and Vref− and including Vcm_in(t) associated with the differential inputs Vin+(t) and Vin−(t). During operation, an active state of clock p1 provides for sampling of the input signal Vin (FIG. 4B) and an active state of clock p2 provides for sampling of Vref along with providing the integration function (FIG. 4C).

Referring to FIG. 4B, when clock p1 is in the active state, the two sampling capacitors Cs have a common terminal connected to the common mode voltage Vcm (AC ground) and the switches associated with clock p1 connect each of the opposite side capacitor terminals to Vcm_in(t). This produces a voltage ΔVcm1=Vcm_in(t)−Vcm across each capacitor Cs.

When the clock p2 state is active, the associated switches cause the inputs of the two input capacitors Cs to be connected to Vcm_ref as shown in FIG. 4C. This causes the charge on the sampling capacitors Cs be AVcm2=Vcm_ref−Vcm. This causes a charge to be transferred from capacitors Cs to the two integrating capacitors Ci to produce a voltage across Ci equal to ΔVcm*Cs/Ci where ΔVcm=Vcm_in(t)−Vcm_ref. If there is some mismatch between capacitors Cs, this mismatch will translate the common mode charge transfer to the differential output thereby deteriorating the CMRR of the converter. It can be shown from the foregoing that the CMRR of the FIG. 3 circuit is as follows:

CMRR=1/[[|Vcm_ref−Vcm_{—}int(t)|/(Vcm_{—}in(t)][ΔCs/Cs]]
where ΔCs represents the mismatch between the two sampling capacitors Cs;
Or

CMRR≈Cs/ΔCs (1)

Thus, from equation (1), it can be seen that the CMRR is limited by capacitor matching. Given the typical mismatch ΔCs between capacitors for an actual implementation, the maximum CMRR is less than 80 dB, a relatively poor value for many high precision applications.

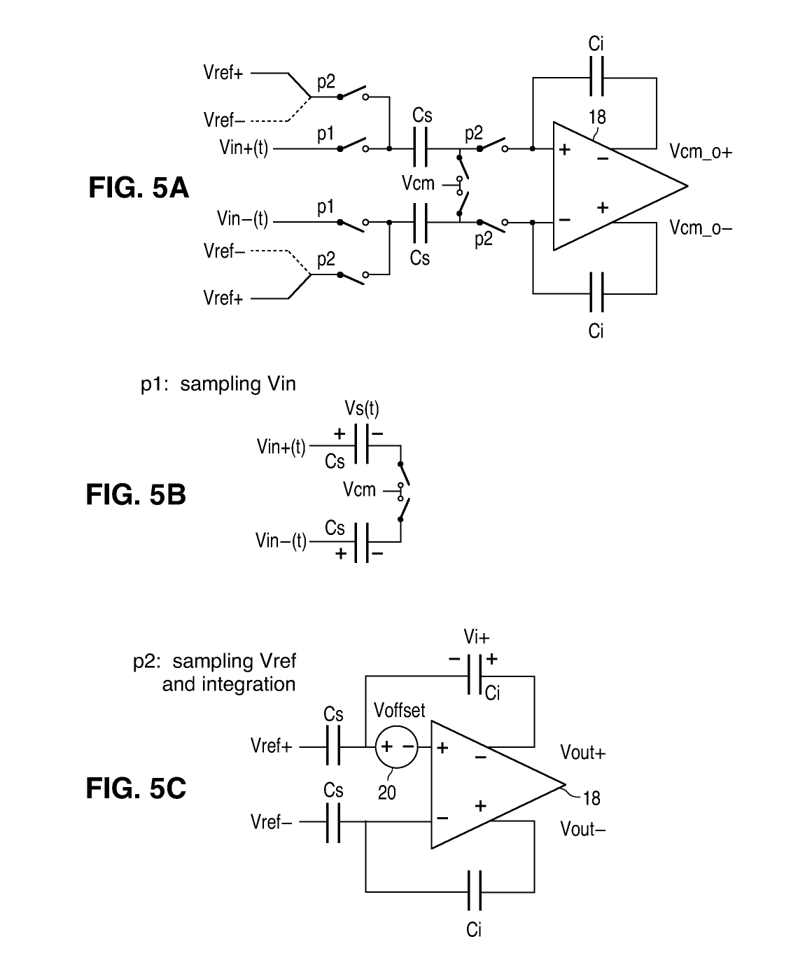

FIGS. 5A-5C illustrate the noise and offset voltage limitations of the prior art converter of FIG. 3. FIG. 5A shows, among other things, the manner in which the reference voltages Vref+ and Vref− are switched with one another depending upon the state of ADC 16 of FIG. 3. When the state of clock p1 is active as shown in FIG. 5B, the differential inputs Vin+(t) and Vin−(t) are sampled and stored on respective sampling capacitors Cs. By way of example, a voltage Vs(t) which is stored on the sampling capacitor Cs connected to Vin+(t), where Vs(t) is equal to Vin+(t)−Vcm.

When the state of clock p2 is active, the reference voltages, Vref+ and Vref−, are sampled and integration takes place as indicated by FIG. 5C. Element 20 represents the input offset voltage Voffset of operational amplifier 18. During this time, the charge transferred to the upper integration capacitor Ci produces a voltage V1+ across the capacitor equal to (Vin+(t)−Vref+)*Cs/Ci. In addition, the charge transferred to the lower integration capacitor Ci produces a voltage Vi− across that capacitor equal to (Vin−(t)−Vref−)*Cs/Ci. The differential output voltage (Vout+−Vout−) is equal to the sum of Voffset and the voltage difference between the voltages on the upper and lower integration capacitors Ci.

It can be seen from the foregoing that offset in the output voltage Vout is limited by the offset voltage of the operational amplifier. In addition, the 1/f noised is also limited by the 1/f noise of the amplifier.

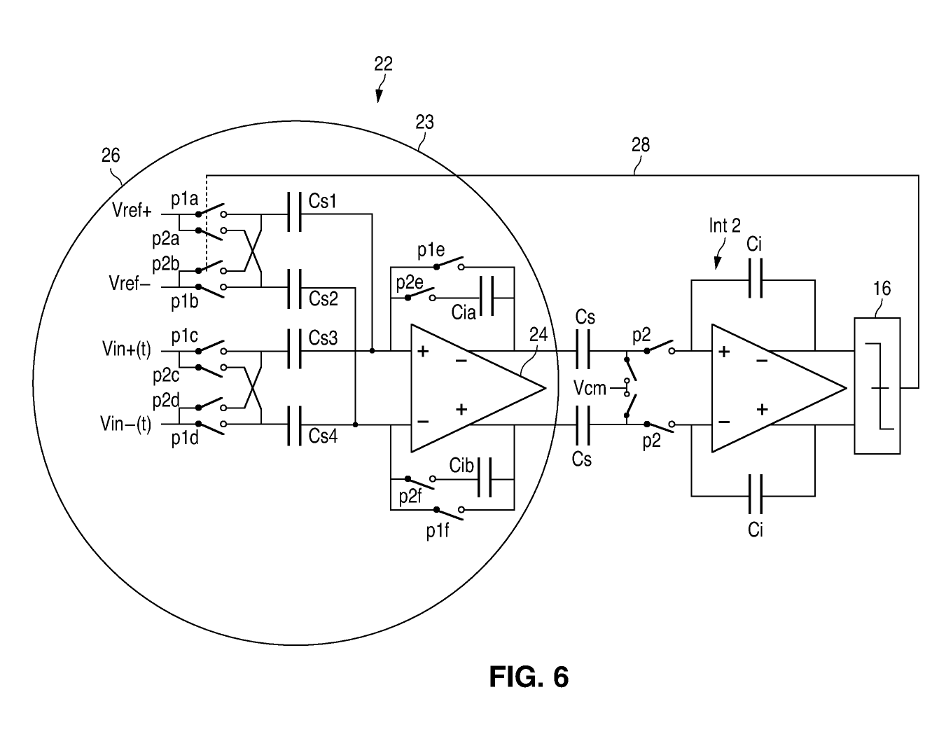

FIG. 6 shows one embodiment 22 of the present invention. The ΣΔADC 22 includes a first integrator and other associated circuitry enclosed by circle 23 followed by a second integrator INt2 which is in turn followed by an ADC circuit 16, sometimes referred to herein as a quantizer circuit. The output of ADC 16 is fed back to the input of converter 22 as represented by line 28. ADC 16 in the depicted example is a one bit converter which selects one of two reference voltages Vref+ and Vref− based upon the state of the output. The two reference voltages are effectively reversed depending upon the state of the digital output of ADC 16 as will be described.

The embodiment includes an operational amplifier 24 along with two sampling capacitors Cs1 and Cs3 having one common terminal connected to the non-inverting amplifier input and two additional sampling capacitors Cs2 and Cs4 having one common terminal connected to the inverting input of the amplifier. The four sampling capacitors are of the same value. The remaining terminal of capacitor Cs1 is connected to respective terminals of switches p1a and p2b, with the remaining terminal of capacitor Cs3 being connected to the respective terminals of switches p1c and p2d. The remaining terminal of capacitor Cs2 is connected to the respective terminals of switches p2a and p1b and the remaining terminal of capacitor Cs4 is connected to the respective terminals of switches p2c and p1d.

An integrating capacitor Cia is connected intermediate the non-inverting input and inverted output of the amplifier by switch p2e, with another integrating capacitor Cib being connected intermediate the inverting input and non-inverted output of the amplifier by a switch p2f. The integrating capacitors are the same value. Finally, the non-inverting input and inverted output of amplifier 24 are selectively connected together by a switch pie, with the inverting input and non-inverting output of the amplifier being selectively connected together by a switch p1f.

In the event an ADC 16 is used having a two bit output rather than one, another set of sampling capacitors equivalent to Cs1 and Cs2 is provided along with associated switches equivalent to p1a, p2a, p2b and p1b along with a set of new reference voltages Vref+/2 and Vref−/2. Each additional bit would require a further set of sampling capacitors and switches and an additional pair of reference voltages.

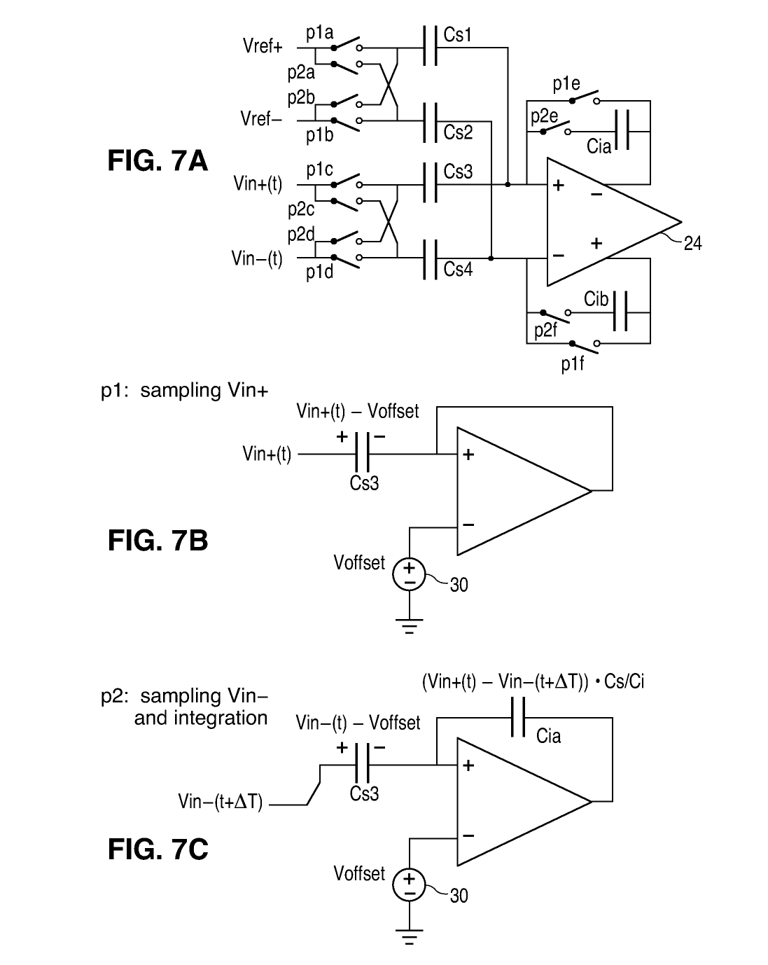

FIGS. 7A to 7C illustrate certain aspects of the operation of the FIG. 6 embodiment, with a partial single-ended analysis being used for purposes of clarity. Once again, one clock (clock p1) is used to control the states of switches pix, with another clock (clock p2) being used to control the states of switches p2x. FIG. 7B shows the case where clock p1 is active so that the inputs and outputs of the amplifier are shorted together. In addition, input Vin+(t) is connected to sampling capacitor Cs3. The amplifier input offset voltage is represented by element 30. Thus, a voltage equal Vin+(t)−Voffset is stored on capacitor Cs3

When clock p2 is active, as illustrated in FIG. 7C, the input Vin− is sampled. Since time ΔT has lapsed since Vin+(t) was just sampled, the input is expressed as Vin−(t+ΔT). Since the sampling rate frequency is much higher than the frequency of Vin, it can be safely assumed that Vin has not changed over ΔT. This action causes a charge to be transferred to the integration capacitor Cia equal to (Vin+(t)−Vin−(t+ΔT))*Cs/Ci which is approximately equal to 2*Vin(t)*Cs/Ci. This approach where Vin is effectively sampled twice is referred to as correlated double sampling.

In the case of non-correlated double sampling in a prior art sigma-delta modulator, the signal is only sampled in one phase (p1 for example) while the noise is sampled in two phases (p1 and p2). For correlated double sampling, both signal and noise are sampled twice so that the signal-to-noise ratio (SNR) is doubled. Since the signal is doubled at a constant kT/C, lower power operation is permitted. In addition, the auto-zero feature reduces offset and the 1/f noise.

As previously noted, the ADC output on line 28 is used to reverse the polarity of the reference voltage Vref by switching phases Vref+ and Vref−. By way of example, this can be carried out by reversing the clock signals to switches p1a, p2a, p2b and p1b (FIG. 6) when ADC 16 changes stage. Thus, when the output of ADC 16 on line 28 is in a first state, Vref+ is connected to the input side of capacitor Cs1 when clock p1 is active and is connected to the input side of capacitor Cs2 when clock p2 is active. Should the ADC 16 output change to a second state, the clock signals to switches p1a and p2a are effectively reversed so that when clock p1 is active, Vref+ is connected to the input side of capacitor Cs2 and Vref− is connected to the input side of capacitor Cs1 when clock p2 is active. Similarly, the clock signals to switches p2b and p1b associated with Vref− are also effectively reversed when the ADC changes from one state to another.

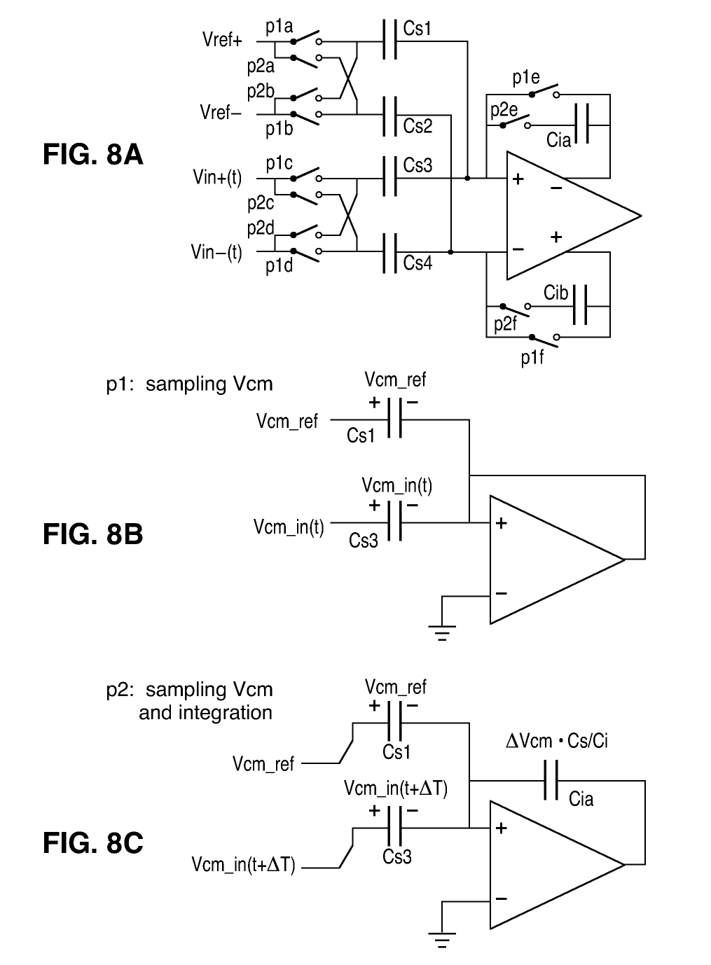

FIGS. 8A-8C illustrate the CMRR characteristics of the FIG. 6 embodiment of the present invention. Single ended operation is described for purposes of simplicity, with this mode of operation being applicable to differential operation. FIG. 8B shows single sided operation when clock p1 is active. Once again, switch p1e connects the amplifier output to the input. Switch p1a connects the input side of sampling capacitor Cs1 to the common mode voltage for Vref referred to as Vcm_ref and switch p1c connects the input side of sampling capacitor Cs3 to the common mode voltage for Vin referred to as Vcm_in(t). Thus, since the capacitor terminals connected to the non-inverting input are held at virtual ground due to amplifier feedback, the respective voltages stored on capacitors Cs1 and Cs3 are Vcm_ref and Vcm_int(t).

When clock p2 is active, as indicated in FIG. 8C, the common mode voltages are again sampled and an integration is carried out. The Vref common mode voltage Vcm_ref is connected to the outer terminal of capacitor Cs1 and the Vin common mode voltage is sampled a second time to produce Vcm_in(t+ΔT) which is connected to the outer terminal of capacitor Cs3. Thus, a charge is transferred to integration capacitor Cia which produces a voltage equal to ΔVcm*Cs/C1 where ΔVcm is equal to Vcm(t)−Vcm (t+ΔT), with theses terms including the changes in Vcm-ref and changes in Vcm-in(t) between the two samples. This value will be small since the common mode voltages are usually at a low frequency (i.e., 50/60 Hz) and will not change significantly between the short sampling periods. The CMRR can be expressed as follows:

CMRR=1/[[(Vcm_in(t)−Vcm_in(t+ΔT))/Vcm_in (t)][ΔCs/Cs]]

or

=(2fs/fcm_{—}in)*(Cs/ΔCs) (2)
where
   fs is he sampling frequency; and
   fcm_in is the common mode frequency of the input signal.

Thus, it can be seen the correlated double sampling greatly attenuates the common mode signals when the sampling frequency fs is made much higher that the common mode frequency fcm_in. By way of example, in the case of ECG monitoring equipment, the most prevalent noise source which results in high common mode voltages are AC power sources having a frequency of 50/60 Hz. A sampling frequency fs of 100 kHz is adequate to accommodate a maximum ECG signal of 200 Hz and is much larger than the common mode frequency fcm_in of 50/60 Hz. Thus, the high level common mode voltages at 50/60 Hz do not interfere with accurate ECG measurements. By way of example, for in input common mode signal of 1 V at 50 Hz and with a sampling capacitor mismatch of 0.1%, the CMRR of the FIG. 6 embodiment of the present invention is 122 dB whereas prior art converters as shown in FIG. 2 typically have a CMRR value of only 66 dB.

It should also be noted that the double sampling and auto-zero attributes of the FIG. 6 embodiment also results in a high common mode voltage range (CMVR) which is valuable in many applications. As previously discussed in connection with FIGS. 8A-8C, all of the common mode voltages are taken up by the sampling capacitors Cs1 to Cs4, with only a small portion of the common mode voltage being transferred to the integration capacitors Cia and Cib. Accordingly, the CMVR of the integrator is limited by the input switches p1a, p2a, p1b, p2b, p1c, p1c, p1d and p2d and the sampling capacitors Cs1, Cs2, Cs3 and Cs4 at the input and not by the amplifier of the integrator. Because of this, a CMVR extending from rail to rail is easy to achieve. In fact, if the input switches and associated drive circuitry are properly implemented, it is possible to achieve a CMVR in excess of rail to rail. This feature is very useful in some applications such as battery monitoring for electric cars, where very high CMVR and CMRR performance is needed, but a high input impedance is not needed. Thus, the typical front end operational amplifiers needed by prior art converters in this application to provide a high input impedance are not needed thereby saving power. Further, by eliminating these input amplifiers, the CMRR and CMVR limitations imposed by these amplifiers are also eliminated. Thus, as previously described, the achievable CMVR can even substantially exceed the rail to rail power supply voltages.

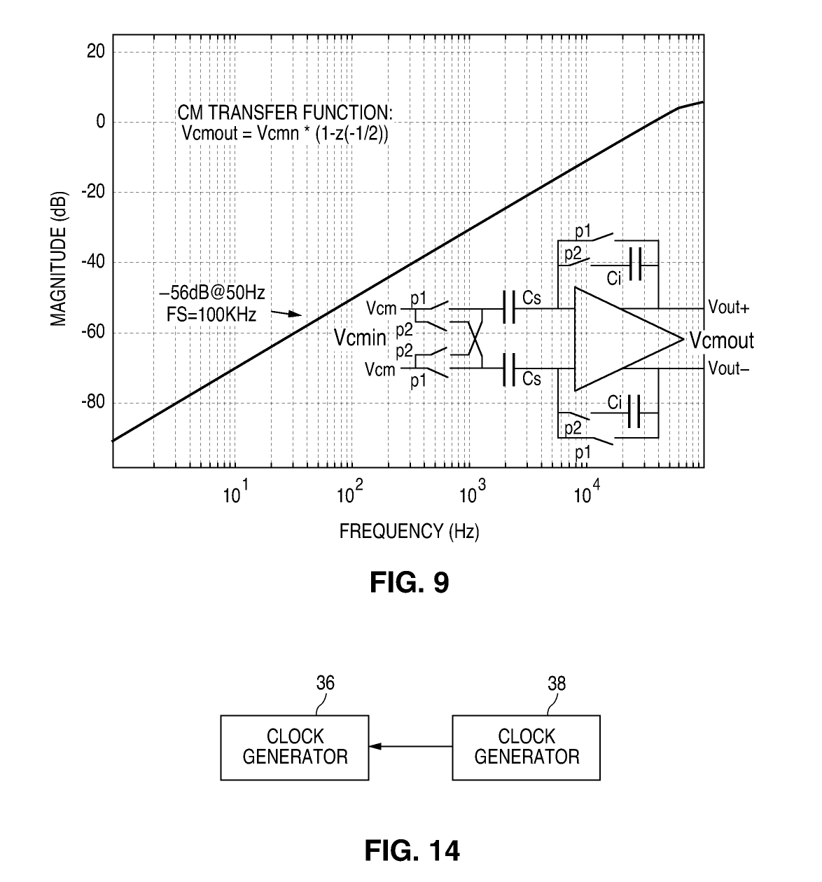

FIG. 9 is a circuit model further illustrating the common mode characteristics of one embodiment of the present invention over changes in the common mode frequency fcm_in. An analysis is more easily carried out in the z domain. Assume that Vcm_int(t+ΔT) is the current state. Then the following is true:

Vcm_in(t)=Vcm_int(t+ΔT)*z(−½)

then

(Vcm_in(t)−Vcm_int(t+ΔT))/Vcm_in(t+ΔT)=1−z(−½)

or, simpifying

Vcm_out=Vcm_in*(1−z(−½)) (3)

Equation (3) is a 1^{st} order high-pass function as can be seen in the FIG. 9 plot. When the input frequency is fcm_in, the attenuation is fcm_in/2fs where fs is the sampling frequency. (See equation (2) also, along with the related discussion.) The transfer function is plotted in FIG. 9 and shows a common mode gain of only −56 dB at the frequency of interest (50 Hz).

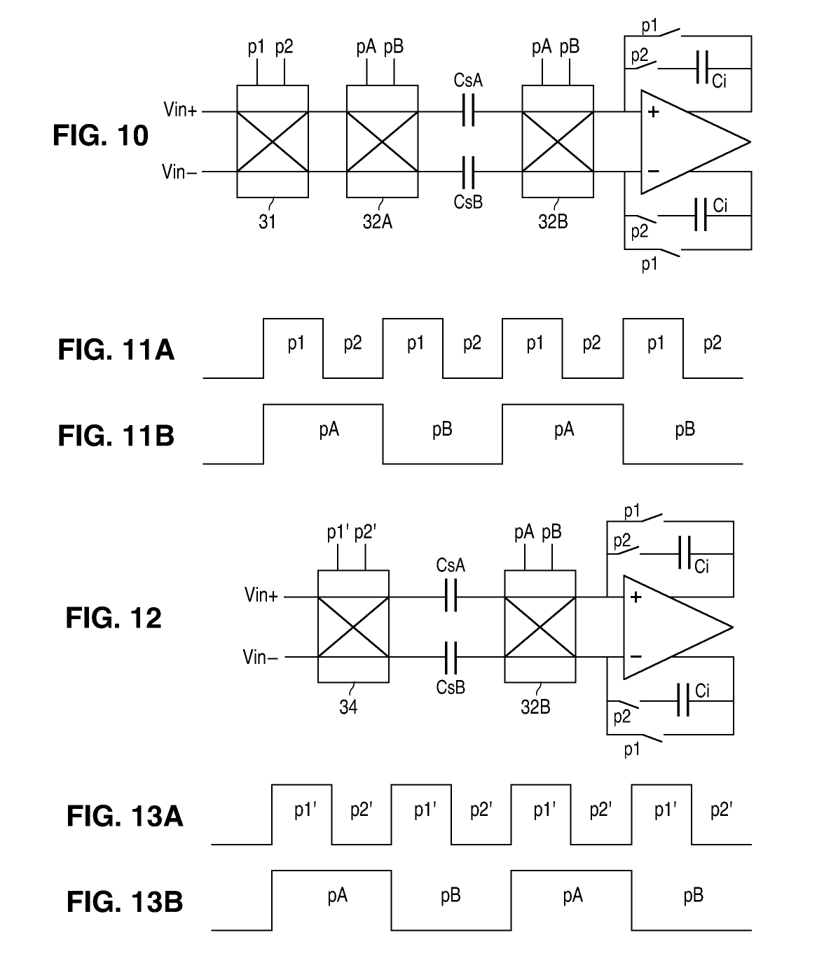

FIG. 10 shows a modification of the FIG. 6 embodiment which combines the correlated double sampling feature with a dynamic element matching feature. As is well known, dynamic element matching involves effectively matching of circuit elements by periodically interchanging or swapping the elements. This results in both of the switched element values being effectively replaced with to an equivalent single average value. In this case, the sampling capacitors CsA and CsB are periodically swapped each clock cycle using switching networks 32A and 32B. Switching network 31 includes four switches such as switches p1c, p1c, p2d and p1d of the FIG. 6 embodiment where the sampling capacitors CsA and CsB correspond to respective capacitors Cs3 and Cs4. Switching networks 32A and 32B each also include four switches for making the connections represented by the horizontal lines when a clock pA is active and for making the connections represented by the diagonal lines when a clock pB is active.

FIG. 11A shows the relative timing of clocks p1 and p2, with the timing of the two clocks being one full clock cycle. FIG. 11B shows the timing of clocks pA and pB used to control switching networks 32A and 32B. It can be seen that the two clocks pA and pB are each active for a full clock cycle. When clocks pA is active along with clock p1, the inputs Vin+ and Vin− are connected to the input side of respective capacitors CsA and CsB, as represented by the horizontal line across elements 31 and 32A. In addition, network 32B connects output side of capacitors CsA and CsB to the respective non-inverting and inverting inputs of the differential amplifier. When clock p2 becomes active (while clock pA is still active), the switches of network 31 represented by the diagonal lines are ON so that input Vin+ is now connected to the input side of capacitor CsB and input Vin− is connected to the input sides of capacitor CsA. When clock pB becomes active, clocks p1 and p2 perform the same function except that the input and output terminals of capacitors CsA and CsB are swapped. Thus, dynamic element matching of the two capacitors is achieved.

Similar switching networks can be provided to swap capacitors Cs1 and Cs2 of the FIG. 6 embodiment. Note also that the functionality of switching networks 31 and 32A can be combined so that the same set of switches can perform both functions. FIG. 12 shows a further embodiment where the eight switches of networks 31 and 32A are combined to a single network 34 of four switches. The two switches of network 34 for making the horizontal connections are controlled by a modified clock p1′ and the two switches for making the diagonal connections are controlled by a modified clock p2′. The modified clocks p1′ and p2′ for controlling the switches of network 34 are depicted in the timing diagram of FIG. 13A. The clocks pA and pB shown in FIG. 13B for controlling network 32B remain unchanged as are clocks p1 and p2 (FIG. 11A) for controlling, among other things, the state of the integrating capacitors Ci. Thus, once again correlated double sampling and dynamic element matching are both carried out.

Note that the various clocks signals p1, p2, pA, pB, p1′ and p2′ can all be produced by a clock generator 36 as shown in FIG. 14, with the generator 36 clocks being controllable by a controller 38. The particular implementation of generator 36 and controller 38 is straightforward and forms no part of the present invention, with implementation details not being provided so as to avoid obscuring description of the invention in unnecessary detail.

Thus, various embodiments of the present invention have been disclosed. The improved performance of the disclosed embodiments is substantial. By way of example, without correlated double sampling, the CMRR is only 66 dB. With correlated double sampling the CMRR is increased to 122 dB. With both correlated double sampling and dynamic element matching the CMRR is in excess of 140 dB. Although these embodiments have been described in some detail, it is to be understood that various changes can be made by those skilled in the art without departing from the spirit and scope of the present invention as defined by the appended claims.

What is claimed is:

1. A analog-to-digital converter comprising:
first and second nodes for receiving respective first and second reference signals;
third and fourth nodes for receiving respective first and second input signals of a differential analog input signal pair to be converted;
an input stage including,
(a) a differential amplifier having a non-inverting input and an inverting input and a differential output including an inverted output and a non-inverted output;
(b) first, second, third and fourth sampling capacitors, each having first and second terminals, with the first terminals of the first and second capacitors being coupled to opposite ones of the non-inverting and inverting differential amplifier inputs and with the first terminals of the third and fourth capacitors being coupled to opposite ones of the non-inverting and inverting differential amplifier inputs;
(c) a first switching network having a first state where the first node is coupled to the second terminal of the first capacitor and the second node is coupled to the second terminal of the second capacitor and a second state where the first node is coupled to the second terminal of the second capacitor and the second node is coupled to the second terminal of the first capacitor;
(d) a second switching network having a first state where the third node is coupled to the second terminal of the third capacitor and the fourth node is coupled to the second terminal of the fourth capacitor and a second state where the third node is coupled to the second terminal of the fourth capacitor and the fourth node is coupled to the second terminal of the third capacitor;
(e) first and second integrating capacitors;
(f) a third switching network having a first state where the non-inverting input of the differential amplifier is coupled to the inverted output and the inverting input is coupled to the non-inverted output and a second state where the first integrating capacitor is coupled between the non-inverting input and the inverted output of the differential amplifier and the second integrating capacitor is coupled between the inverting input and the non-inverted output of the differential amplifier; and
(g) a mode controller configured to switch the input stage between a sampling mode and a sampling/integration mode, wherein during the sampling mode, the first, second and third switching networks are in the first state and during the sampling/integration mode the first, second and third switching networks are in the second state; and
a quantizer circuit, responsive to the differential output of the amplifier of the input stage and configured to produce a quantized output indicative of a magnitude of the differential analog input signal pair.

2. The analog-to-digital converter of claim 1 further including an integration stage disposed intermediate the input stage and the quantizer circuit.

3. The analog-to-digital converter of claim 1 where the input stage further includes a fourth switching network disposed intermediate the first terminals of the third and fourth sampling capacitors and the non-inverting input and inverting input of the differential amplifier and wherein the mode controller is further configured to periodically control the second and fourth switching networks so that electrical connections of the third and fourth sampling capacitors are periodically swapped so as to provide dynamic element matching of the third and fourth sampling capacitors.

4. The analog-to-digital converter of claim 3 where the input stage further includes a fifth switching network disposed intermediate the first terminals of the first and second sampling capacitors and the non-inverting input and inverting input of the differential amplifier and wherein the mode controller is further configured to periodically control the first and fifth switching networks so that electrical connections of the first and second sampling capacitors are periodically swapped so as to provide dynamic element matching of the first and second sampling capacitors.

5. The analog-to-digital converter of claim 4 wherein the quantized output is used to control which of the first and second phases of the reference signal is applied to the second terminals of the respective first and second sampling capacitors when the input stage is in the sampling mode.

6. The analog-to-digital converter of claim 5 wherein the first switching network includes a first switch connected intermediate the first node and the second terminal of the first sampling capacitor, a second switch connected intermediate the second node and the second terminal of the second sampling capacitor, a third switch connected intermediate the first node and the second terminal of the second sampling capacitor and a fourth switch connected intermediate the second node and the second terminal of the first sampling capacitor.

7. The analog-to-digital converter of claim 5 wherein the second switching network includes a first switch connected intermediate the third node and the second terminal of the third sampling capacitor, a second switch connected intermediate the fourth node and the second terminal of the fourth sampling capacitor, a third switch connected intermediate the third node and the second terminal of the fourth sampling capacitor and a fourth switch connected intermediate the fourth node and the second terminal of the third sampling capacitor.

8. The analog-to-digital converter of claim 5 wherein the third switching network includes a first switch connected intermediate the non-inverting input and inverted output of the differential amplifier, a second switch connected intermediate the inverting input and non-inverted output of the differential amplifier, a third switch connected in series with the first integrating capacitor and a fourth switch connected in series with the second integrating capacitor.

9. The analog-to-digital converter of claim 5 wherein the fourth switching network includes a first switch connected intermediate the first terminal of the third sampling capacitor and one of the inputs of the differential amplifier, a second switch connected intermediate the first terminal of the fourth sampling capacitor and another one of the inputs of the differential amplifier, a third switch connected intermediate the first terminal of the third sampling capacitor and the another one of the inputs of the differential amplifier and a fourth switch connected intermediate the first terminal of the fourth sampling capacitor and the one of the inputs of the differential amplifier.

10. The analog-to-digital converter of claim 5 wherein the fifth switching network includes a first switch connected intermediate the first terminal of the first sampling capacitor and one of the inputs of the differential amplifier, a second switch connected intermediate the first terminal of the second sampling capacitor and another one of the inputs of the differential amplifier, a third switch connected intermediate the first terminal of the first sampling capacitor and the another one of the inputs of the differential amplifier and a fourth switch connected intermediate the first terminal of the second sampling capacitor and the one of the inputs of the differential amplifier.

11. A analog-to-digital converter comprising:
first and second nodes for receiving respective first and second reference signals;
third and fourth nodes for receiving respective first and second input signals of a differential analog input signal pair to be converted;
an input stage including,
(a) a differential amplifier having a non-inverting input and an inverting input and a differential output including an inverted output and a non-inverted output;
(b) first through fourth connection points for receiving a first terminal of respective first, second, third and fourth sampling capacitors and fifth through eighth connection points for receiving a second terminal of the respective first, second, third and fourth sampling capacitors, with the fifth and sixth connection points being coupled to opposite ones of the non-inverting and inverting differential amplifier inputs and with the seventh and eight connection points being coupled to opposite ones of the non-inverting and inverting differential amplifier inputs;
(c) a first switching network having a first state where the first node is coupled to the first connection point and the second node is coupled to the second connection point and a second state where the first node is coupled to the second connection point and the second node is coupled to the first connection point;
(d) a second switching network having a first state where the third node is coupled to the third connection point and the fourth node is coupled to the fourth connection point and a second state where the third node is coupled to the fourth connection point and the fourth node is coupled to third connection point;
(e) ninth and tenth connection points for receiving a first terminal of respective first and second integrating capacitors and eleventh and twelfth connection points for receiving a second terminal of the respective first and second integrating capacitors;
(f) a third switching network having a first state where the non-inverting input of the differential amplifier is coupled to the inverted output and the inverting input is coupled to the non-inverted output of the differential amplifier and a second state where the ninth connecting point is coupled to the non-inverting input, the tenth connection point is coupled to the inverted output of the differential amplifier, the eleventh connecting point is coupled to the inverting input and the twelfth connecting point is coupled to non-inverted output of the differential amplifier; and
(g) a mode controller configured to switch the input stage between a sampling mode and a sampling/integration mode, wherein during the sampling mode the first, second and third switching networks are in the first state and during the sampling/integration mode the first, second and third switching networks are in the second state;
a quantizer circuit, responsive to the differential output of the amplifier of the input stage and configured to produce a quantized output indicative of a magnitude of the differential analog input signal pair.

12. The analog-to-digital converter of claim 11 where the input stage further includes a fourth switching network disposed intermediate the seventh and eighth connecting points and the non-inverting input and inverting input of the differential amplifier and wherein the mode controller is further configured to periodically control the second and fourth switching networks so that electrical connections to the third and seventh connecting points are periodically swapped with electrical connections to the fourth and eighth connection points so as to provide dynamic element matching of the third and fourth sampling capacitors when the capacitors are present.

13. The analog-to-digital converter of claim 12 where the input stage further includes a fifth switching network disposed intermediate the fifth and sixth connecting points and the non-inverting input and inverting input of the differential amplifier and wherein the mode controller is further configured to periodically control the first and fifth switching networks so that electrical connections to the first and second connecting points are periodically swapped with electrical connections to the fifth and sixth connection points so as to provide dynamic element matching of the first and second sampling capacitors when the capacitors are present.

14. The analog-to-digital converter of claim 13 wherein the quantized output is used to control which of the first and second phases of the reference signal is applied to the respective first and second connection points when the input stage is in the sampling mode.

15. The analog-to-digital converter further including an integrator circuit disposed intermediate the input stage and the quantizer circuit with the quantizer circuit also being responsive to an output of the integrator circuit.

16. A method of converting a differential analog input signal pair to a digital signal comprising:
providing first, second, third and fourth sampling capacitors, each having first and second terminals;
maintaining the first terminals of the first, second, third and fourth sampling capacitors at substantially a same voltage;
during a sampling phase, connecting the second terminals of the first and second sampling capacitors to respective first and second reference signals and connecting the second terminals of the third and fourth sampling capacitors to respective first and second input signals of a differential analog input signal pair to be converted;
during a sample/integration phase subsequent to the sampling phase,
(a) connecting the second terminals of the first and second sampling capacitors to the respective second and first reference signals,
(b) connecting the second terminals of the third and fourth sampling capacitors to the respective second and first input signals,
(c) transferring charge on the first and third sampling capacitors to a first integrating capacitor,
(d) transferring change on the second and fourth sampling capacitors to a second integrating capacitor;
providing an integrated output signal derived from the charge transferred to the first and second integrating capacitors; and
quantizing a signal related to the integrated output signal to produce the digital signal.

17. The method of claim 16 wherein the first terminals of the first and third capacitors are connected together at a first node, the first terminals of the second and third capacitors are connected together at a second node, and wherein the first and second nodes are maintained substantially at the same voltage by way of negative feedback of an amplifier circuit.

18. The method of claim 16 wherein electrical connections of the first and second sampling capacitors are periodically reversed to provide dynamic element matching of the first and second sampling capacitors.

19. The method of claim 16 wherein electrical connections of the third and fourth sampling capacitors are periodically reversed to provide dynamic element matching of the third and fourth sampling capacitors.

20. The method of claim 17 wherein the amplifier circuit is a differential amplifier and wherein during the sample/integration phase, one of the first and second integrating capacitors is connected between an inverting input and non-inverted output of the differential amplifier and the other one of the first and second integrating capacitors is connected between a non-inverting input and an inverted output of the differential amplifier.
